(19) United States
(12) Patent Application Publication
(10) Pub. No.: US 2021/0384219 A1
(43) Pub. Date: Dec. 9, 2021

(54) CONTACT PAD STRUCTURE AND METHOD OF FORMING THE SAME

(71) Applicant: Yangtze Memory Technologies Co., Ltd., Wuhan (CN)

(72) Inventors: Di WANG, Wuhan (CN); Wenxi ZHOU, Wuhan (CN); Zhiliang XIA, Wuhan (CN); Yonggang YANG, Wuhan (CN); Kun ZHANG, Wuhan (CN); Hao ZHANG, Wuhan (CN); Yiming AI, Wuhan (CN)

(73) Assignee: Yangtze Memory Technologies Co., Ltd., Wuhan (CN)

(21) Appl. No.: 17/190,601

(22) Filed: Mar. 3, 2021

Related U.S. Application Data
(63) Continuation of application No. PCT/CN2020/094582, filed on Jun. 5, 2020.

(51) Int. Cl. H01L 27/11582; H01L 27/11556; H01L 27/11519; H01L 27/11565; H01L 23/00

(52) U.S. Cl. CPC H01L 27/11582; H01L 27/11556; H01L 24/08; H01L 27/11565; H01L 24/03; H01L 27/11519

(57) ABSTRACT

Aspects of the disclosure provide a semiconductor device and a method for fabricating the same. The method for fabricating the semiconductor device can include forming a stack of alternating first insulating layers and first sacrificial layers over a semiconductor substrate, and forming a staircase in the stack having a plurality of steps, with at least a first step of the staircase including a first sacrificial layer of the first sacrificial layers over a first insulating layer of the first insulating layers. Further, the method can include forming a recess in the first sacrificial layer, forming a second sacrificial layer in the recess, and replacing a portion of the first sacrificial layer and the second sacrificial layer with a conductive material that forms a contact pad.

### RELATED APPLICATION

This application is a bypass continuation of International Application No. PCT/CN2020/094582, filed on Jun. 5, 2020. The entire disclosure of the prior application is hereby incorporated by reference in its entirety.

### BACKGROUND

Flash memory devices are widely used for electronic data storage in various modern technologies, e.g., smart phones, computers, and the like. To increase memory density and reduce fabrication cost, three-dimensional (3D) NAND flash memory devices have been developed. A key step in manufacturing a 3D NAND device is to form contact holes by high-aspect-ratio etching. With an increasing number of layers required by a 3D NAND device, contact holes are inevitably deepened, which imposes a challenge on the high-aspect-ratio etching process. Over-etching can result in bridging between word lines while under-etching will lead to failure in creating a word line contact.

### SUMMARY

Aspects of the disclosure provide a contact pad technology for contact structures in a semiconductor device and the method of forming contact pads.

According to a first aspect, a semiconductor device with a contact pad configuration is disclosed. The semiconductor device can include a substrate and a staircase formed over the substrate with a plurality of steps. At least a step of the plurality of steps can include a first insulating layer and a second layer arranged over the first insulating layer, with the second layer including an insulating portion and a conductive portion.

The semiconductor device can also include a contact pad arranged over the insulating portion and conductive portion of the second layer. The contact pad has a thickness so that an upper surface of the contact pad can be between an upper surface and a lower surface of the first insulating layer of an adjacent step located immediately above the first step. The contact pad can be made of a same material as and integrally formed with the conductive portion of the second layer.

The semiconductor device can also include two walls positioned on opposite sides of the staircase that are formed of alternating first insulating layers and conductive layers that are vertically stacked over the substrate. The first insulating layers of the walls can be an extension of a corresponding first insulating layer of the step in two opposite directions. The conductive portion of the second layer is an extension of a corresponding conductive layer of the wall. The insulating portion of the second layer is a second insulating layer made of a different material than the first insulating layers of the wall.

The semiconductor device can further include a third insulating layer that is formed over the contact pad and extends to an upper surface of the wall. The semiconductor device can also include a contact structure that extends through the third insulating layer to the upper surface of the contact pad.

In some embodiments, the semiconductor device can include an array of channel structures that are formed in the alternating first insulating layers and conductive layers that are stacked over the substrate.

In some embodiments, the semiconductor device can further include two slit structures on the boundaries of the two walls so that the two walls and the staircase are sandwiched between the two slit structures and that the insulating portion of the second layer in a step is located between the two slit structures.

According to a second aspect of the disclosure, a method for fabricating a semiconductor with a contact pad configuration is provided where a stack of alternating first insulating layers and first sacrificial layers are formed over a semiconductor substrate. A staircase can then be formed in the stack that has a plurality of steps, with at least a step of the staircase including a first sacrificial layer of the first sacrificial layers over a first insulating layer of the first insulating layers. Subsequently, a second sacrificial layer can be formed over the first sacrificial layer, with an upper surface of the second sacrificial layer between an upper surface and a lower surface of the first insulating layer of an adjacent step above the corresponding step. The staircase can be on a boundary or in the middle of the stack.

In some embodiments, a recess can be formed in the first sacrificial layer prior to forming a second sacrificial layer over the first sacrificial layer. In an alternative embodiment, instead of recess formation in the first sacrificial layer prior to forming a second sacrificial layer over the first sacrificial layer, a chemical treatment can be performed on a top portion of the first sacrificial layer. The chemical treatment can break chemical bonds and form dangling bonds in the top portion of the first sacrificial layer so that a second sacrificial layer can be formed within and over the chemically treated top portion of the first sacrificial layer.

In the disclosed method, a portion of the first sacrificial layer in a staircase can then be removed to provide access to the second sacrificial layer while at least a remaining portion of the first sacrificial layer under the second sacrificial layer is kept from being removed, so that the conductive material fills the space of the removed second sacrificial layer to form a contact pad over the remaining portion of the first sacrificial layer. The conductive material can also fill the space of the removed first sacrificial layer to form an integral layer with the contact pad. The removal of the portion of the first insulating layer can be achieved by a first wet etching process. A second wet etching process can be performed to remove the second sacrificial layer via the removed first insulating layer.

Further, a conductive material can be deposited into the space of the removed first and second sacrificial layers to form a contact pad. Moreover, a contact structure can be formed in conductive connection with the contact pad.

Further, at least an array of channel structures can be formed in the stack. The contact structure can be configured to provide a control signal to the array of channel structures via the contact pad.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be increased or reduced for clarity of discussion.

FIG. 1 is a three-dimensional view of a semiconductor device, in accordance with exemplary embodiments of the disclosure.

FIG. 2 is a top-down view of a semiconductor device, in accordance with exemplary embodiments of the disclosure.

FIG. 3A is a side view of a wall region and a staircase region of the semiconductor device in FIG. 2.

FIG. 3B is a side view of a stepped wall region and a staircase region of an exemplary device.

FIGS. 4A, 4B, and 4C are cross-sectional views taken along the line cuts AA′, BB′, and CC′ in FIG. 2, respectively.

FIGS. 5-11 are cross-sectional views of a semiconductor device at various intermediate steps of manufacturing, in accordance with exemplary embodiments of the disclosure.

FIG. 12 is a cross-sectional view taken along the line cut EE′ in FIG. 7.

FIG. 13 is an alternative embodiment of the manufacturing step illustrated in FIG. 6.

FIG. 14 is a flowchart of an exemplary process for manufacturing an exemplary semiconductor device, in accordance with embodiments of the disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features may be in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

The present disclosure provides a technique for forming contact pads for contact structures of a semiconductor device. The technique can include recess formation, sacrificial layer deposition on the recess, and etching and deposition processes to create a contact pad structure over a stack of insulating layers. The contact pad electrically couples a contact structure with a respective word line. Compared with related examples where a contact structure is in direct contact with a word line over a stack of alternating insulating layers and word lines, the contact pad configuration can allow a contact structure to properly connect with the contact pad, even when the contact structure extends through the contact pad into an underlying portion of the stack.

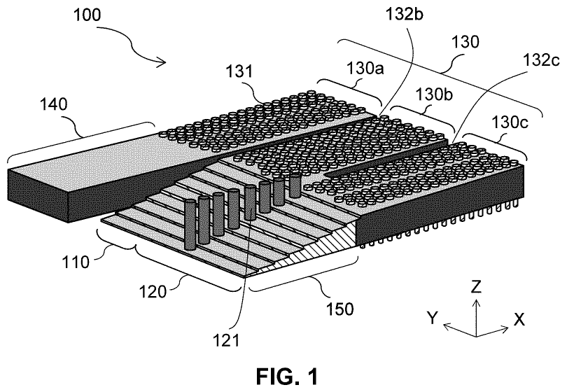

FIG. 1 is a three-dimensional view of an exemplary semiconductor device 100 (referred to as device 100 hereafter). The device 100 can refer to any suitable device, for example, memory circuits, a semiconductor chip (or die) with memory circuits formed on the semiconductor chip, a semiconductor wafer with multiple semiconductor dies formed on the semiconductor wafer, a stack of semiconductor chips, a semiconductor package that includes one or more semiconductor chips assembled on a package substrate, and the like.

As shown in FIG. 1, the device 100 can include a stack that is formed of alternating layers over a substrate. The substrate can be any suitable substrate, such as a silicon (Si) substrate, a germanium (Ge) substrate, a silicon-germanium (SiGe) substrate, and/or a silicon-on-insulator (SOI) substrate. The substrate may include a semiconductor material, for example, a Group IV semiconductor, a Group III-V compound semiconductor, or a Group II-VI oxide semiconductor. The Group IV semiconductor may include Si, Ge, or SiGe. The substrate may be a bulk wafer or an epitaxial layer.

According to some aspects of the disclosure, the device 100 can include an array region 130 with vertical memory cell strings (e.g., 3D NAND cell strings) formed in the stack in the form of arrays, and include a staircase region 150 configured to provide connections to, for example word lines of the vertical memory cell strings. In this example, the staircase region 150 can be divided into a conductive staircase region 110 and an insulated staircase region 120. In some examples, the stack can have a wall region 140 that is arranged adjacent to the staircase region 150. Note that the device 100 can further include a second conductive staircase region besides the insulated staircase region 120 so that the insulated staircase region 120 is sandwiched between the conductive staircase region 110 and the second conductive staircase region (not shown). The device 100 can also include a second wall region besides the second conductive staircase region (not shown).

The device 100 can also have an array region 130 that can include a plurality of channel structures 131 extending through the stack to the substrate. The array region 130 can have a plurality of word lines that are electrically coupled with a plurality of contact structures 121 in the insulated staircase region 120. In an exemplary embodiment of FIG. 1, the device 100 can have two slit structures, 132b and 132c, which divide the array region 130 into three sub-blocks, 130a-130c, also referred to as fingers or finger structures. In further embodiments, the wall region 140 and the staircase region 150 can be formed on more than one side of the array region 130. In alternative embodiments, the wall region 140 and the staircase region 150 can be sandwiched between two array regions. Further, the wall region 140 itself can have a staircase configuration.

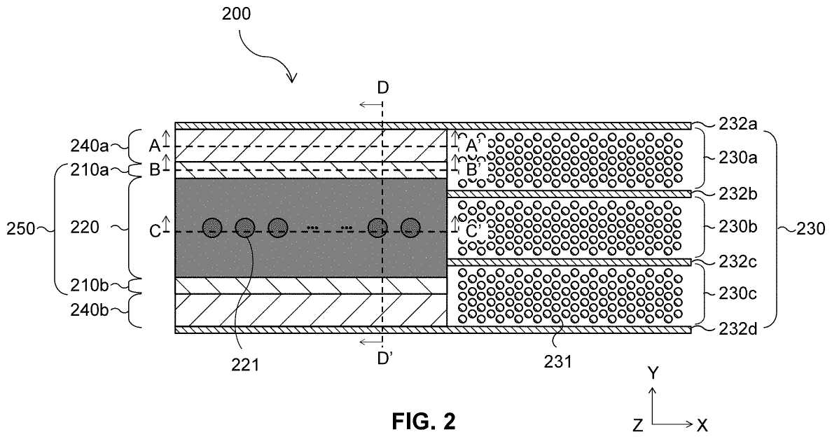

FIG. 2 is a top-down view of an exemplary semiconductor device 200 (hereafter device 200), such as a 3D NAND device. In a similar manner to that shown in FIG. 1, the device 200 can have a staircase region 250 that can be divided into two conductive staircase regions 210a and 210b, and an insulated staircase region 220. In the FIG. 2 example, two wall regions 240a and 240b can be positioned adjacent to the staircase region 250. The device 200 can also include an array region 230 with a plurality of channel structures 231. The array region 230 can have a plurality of word lines that are electrically coupled with a plurality of contact structures 221 in the insulated staircase region 220. As shown, the device 200 can further have two slit structures 232b and 232c which divide the array region 230 into three sub-blocks 230a-230c, also referred to as fingers or finger structures. Two slits structures 232a and 232d can also be included on the boundaries to separate the device 100 from other blocks (not shown).

According to some aspects of the disclosure, the slit structures 232a-232d can be used in a gate-last fabrication technology to facilitate the removal of sacrificial layers and the formation of the real gate layers. In some embodiments, contact structures can be formed in the slit structures 232a-232d. For example, some portions of the slit structures 232a-232d can be made of conductive materials and positioned on array common source (ACS) regions to serve as contacts, where the ACS regions are formed in the substrate to serve as common sources. It is noted that, generally, the slit structures 232a-232d can also include dielectric materials to insulate the contact structures from conductive layers, such as word lines and the like.

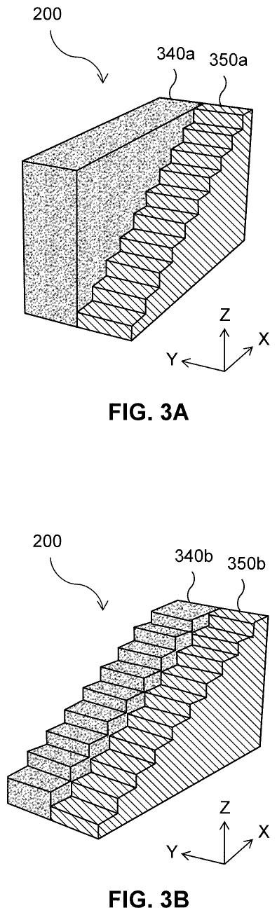

FIGS. 3A and 3B show three-dimensional views of the wall region 240 and the staircase region 250 in FIG. 2. As shown in FIG. 3A, in this example, the device 200 can include a wall region 340a (corresponding to the wall region 240 in FIG. 2) that is arranged besides a staircase region 350a (corresponding to the staircase region 250 in FIG. 2). As shown in FIG. 3B, in another example, the device 200 can have a stepped wall region 340b (corresponding to the wall region 240 in FIG. 2) besides a staircase region 350b (corresponding to the staircase region 240 in FIG. 2).

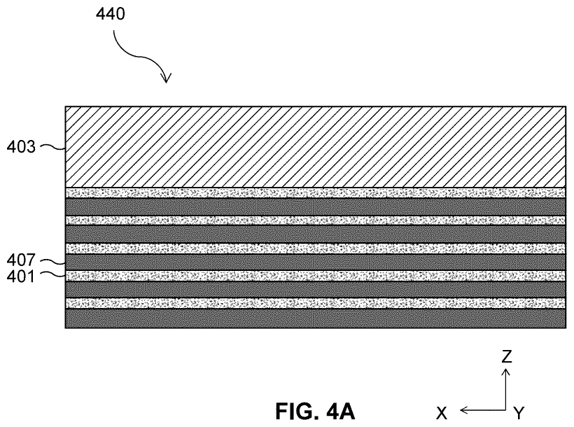

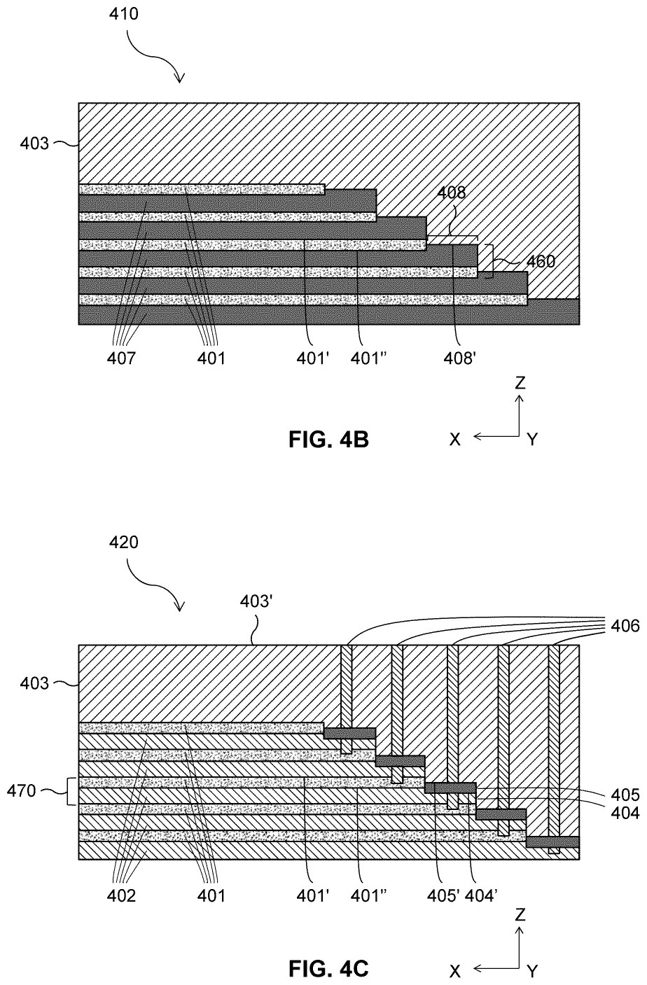

FIG. 4A is a cross-sectional view that is taken along line AA′ in FIG. 2. As shown in FIG. 4A, the wall region 440 (corresponding to the wall region 240) is formed of a stack of alternating conductive layers 407 and first insulating layers 401. Further, a third insulating layer 403 can be formed over the stack. Of course, while FIG. 4A shows five alternating layers of conducting and insulating layers, it should be understood that the number of layers can be varied to meet specific design requirements.

FIG. 4B is a cross-sectional view that is taken along line BB′ in FIG. 2. FIG. 4B shows the conductive staircase region 410 (corresponding to the conductive staircase region 210 in FIG. 2) that is also formed of a stack of alternating conductive layers 407 and first insulating layers 401. As shown, the conductive staircase region 410 can include a plurality of steps 460 with each step 460 having a conductive layer 407 over a first insulating layer 401. The conductive layers 407 and the first insulating layers 401 correspond to the same respective conductive layers 407 and first insulating layers 401 shown in FIG. 4A.

Within each step 460, the conductive layer 407 can be L-shaped to include a projecting portion 408 that extends upwardly. An upper surface 408′ of the projecting portion 408 can extend between an upper surface 401′ and a lower surface 401″ of the first insulating layer 401 of an adjacent step located above the respective conductive layer 407. Of course, while FIG. 4B shows four steps, it should be understood that the number of steps can be varied to meet specific design requirements.

FIG. 4C is a cross-sectional view that is taken along line CC′ in FIG. 2. FIG. 4C shows the insulated staircase region 420 (corresponding to the insulated staircase region 220 in FIG. 2) that can include a plurality of steps 470 that correspond with the steps 460 of the conductive staircase region 410. Each step 470 can include a second insulating layer 402 over a first insulating layer 401. The first insulating layers 401 shown in FIG. 4C correspond to the same respective first insulating layers 401 shown in FIGS. 4A and 4B. The second insulating layers 402 and the first insulating layers 401 can be made of different materials.

A second insulating layer 402 can have a recess 404 that is formed in an upper surface 404′ of the second insulating layer 402. The step 470 can further include a contact pad 405 that is positioned within the recess 404. The contact pad 405 is an extension of the projection 408 shown in FIG. 4B that extends over the second insulating layers 402 within the recess 404. Further, the contact pad 405 has a thickness so that an upper surface 405′ of the contact pad 405 is located between an upper surface 401′ and a lower surface 401″ of a first insulating layer 401 of an adjacent step located immediately above the contact pad 405.

The contact pad 405 serves as a connecting point for respective contact structures 406 that extend from an upper surface 403′ of the third insulating layer 403. The contact structure 406 can be made of the same material as and be integrally formed with the contact pad 405. Hence, the contact structures 406 can be electrically coupled with the conductive layers 407 in the conductive staircase region 410 and the wall region 440 via the contact pad 405. Further, the contact structure 406 can be electrically coupled with a corresponding word line in an array region. Additionally, while the contact structure 406 is shown as extending through the contact pads 405 and into the underlying stack, it should be understood that the contact structure 406 can also extend to the contact pad 405 without extending into the underlying stack.

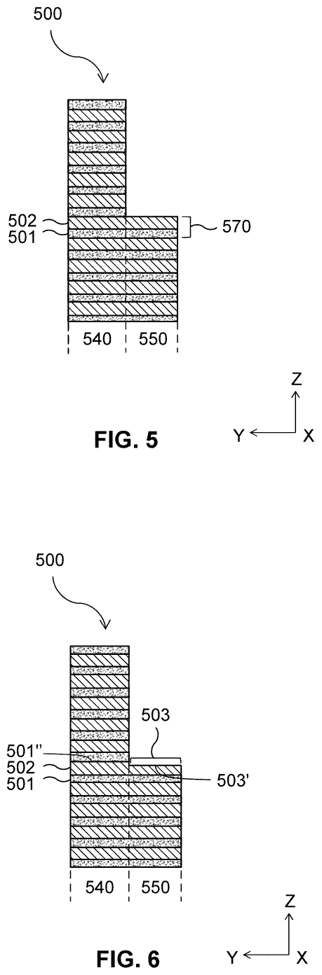

FIGS. 5-11 are cross-sectional views of a semiconductor device, such as the device 100, device 200, and the like at various intermediate steps of manufacturing, in accordance with exemplary embodiments of the disclosure.

FIG. 5 shows a cross-sectional view of a semiconductor device 500 (hereafter device 500 that can correspond to the device 100, the device 200, and the like) that is taken along what will eventually be the line DD′ in FIG. 2 once the manufacturing process is complete. As shown, the device 500 can be formed of a stack of alternating first insulating layers 501 and second insulating layers 502. The stack can have a wall region 540 and a staircase region 550. The staircase region 550 can have a plurality of steps 570, with each step including a second insulating layer 502 over a first insulating layer 501. While not shown in FIG. 5, the steps 570 of the staircase region 550 are arranged to incrementally increase upwards in the z direction. The first insulating layers 501 can be formed by chemical vapor deposition, and can be an insulating material, such as silicon oxide. The second insulating layers 502 can also be formed by chemical vapor deposition, and can be a different insulating material, such as silicon nitride. It is noted that other suitable deposition process, and suitable insulating material can be used for the first insulating layers 501 and the second insulating layers 502.

In FIG. 6, a recess 503 is formed in a top surface 503′ of the second insulating layer 502 in the staircase region 550. The recess 503 can be formed by any technique, such as dry etching. The recess 503 has a thickness so that an upper surface 503′ of the recess 503 is below the lower surface 501″ of the first insulating layer 501 that is located immediately above the respective recess 503. While not shown, similar recesses 503 can also be formed in the second insulating layers 502 of other steps 570 in the staircase region 550.

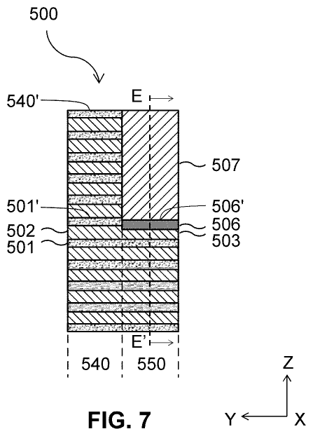

FIG. 7 shows the semiconductor device 500 in FIG. 6 after two deposition processes have been completed. First, a sacrificial layer 506 can be formed in the recess 503 of the second insulating layer 502. The sacrificial layer 506 can be formed so that an upper surface 506′ of the sacrificial layer 506 is below an upper surface 501′ of the first insulating layer 501 located immediately above the respective recess 503. The sacrificial layer 506 can be formed by any process, such as chemical vapor deposition. Further, the sacrificial layer 506 can be a material that is different from the second insulating layer 502, such as polysilicon.

Next, a third insulating layer 507 can be formed over the sacrificial layer 506. As shown, the third insulating layer 507 can extend from an upper surface 540′ of the wall region 540 to the upper surface 506′ of the sacrificial layer 506. The third insulating layer 507 can be formed by chemical vapor deposition, and can be made of an insulating material, such as silicon oxide.

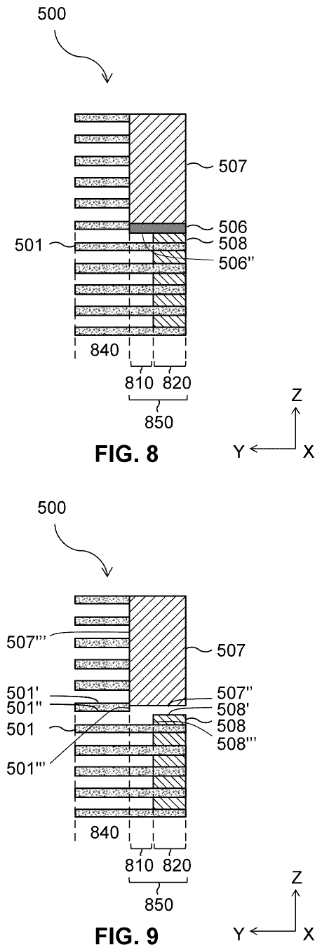

FIG. 8 shows the semiconductor structure 500 in FIG. 7 after a portion of the second insulating layers 502 is removed. As shown, the second insulating layers 502 are completely removed from the wall region 840 (e.g., corresponding to the wall region 140, the wall region 240, the wall region 440 and the like). However, only a portion of the second insulating layers 502 are removed in the staircase region 850 (e.g., corresponding to the staircase region 150, 250, and the like). As a result, the second staircase region 850 is divided into two regions—a first staircase region 810 and a second staircase region 820. In the first staircase region 810, the second insulating layers 502 are completely removed, similar to the wall region 840. In the second staircase region 820, the portion 508 of the second insulating layers 503 remain intact during a process where the second insulating layers 503 are removed in the first staircase region 810 and wall region 840. As also shown, the sacrificial layer 506 remains in the recess 503.

Partial removal of the second insulating layer 502 can be accomplished by any technique, such as a wet etching process. For example, an etchant can be introduced via a pre-formed slit structure, such as a trench corresponding to the slit 232a shown in FIG. 2. The slit structure can be positioned on a boundary of the wall region 840 so that the wall region 840 is sandwiched between the slit structure and the staircase region 850. As a result, the etchant can etch the second insulating layers 502 in the wall region 840 prior to diffusing into the staircase region 850. The etching rate can be calibrated, and the duration of the etching process can be determined by the distance from the slit structure to the second staircase region 820, so that the etching process can be stopped immediately when the etchant reaches the second staircase region 820. Additionally, the etchant can be selected so that it only etches the second insulating layers 502 and does not etch the first insulating layers 501 or the sacrificial layer 506. For example, the etchant can be hot concentrated orthophophoric acid that etches silicon nitride, but does not etch silicon oxide or polysilicon.

FIG. 9 shows the semiconductor structure 500 in FIG. 8 after the sacrificial layer 506 is removed. The removal process can be accomplished by any technique, such as a second wet etching process. For example, a second etchant can be introduced via the same slit structure as the first etchant. Therefore, the second etchant can diffuse into the void of the removed second insulating layers 502 and reach the bottom surface 506″ of the sacrificial layer 506 in FIG. 8. The second etchant can then etch away the entire sacrificial layer 506. While not shown, the sacrificial layers 506 of other steps 570 can also be removed. The second etchant can be selected so that it only etches the sacrificial layer 506 and does not etch the first insulating layers 501 or the second insulating layers 502. For example, the second etchant can be a solution containing tetramethylammonium hydroxide that etches polysilicon, but does not etch silicon oxide or silicon nitride.

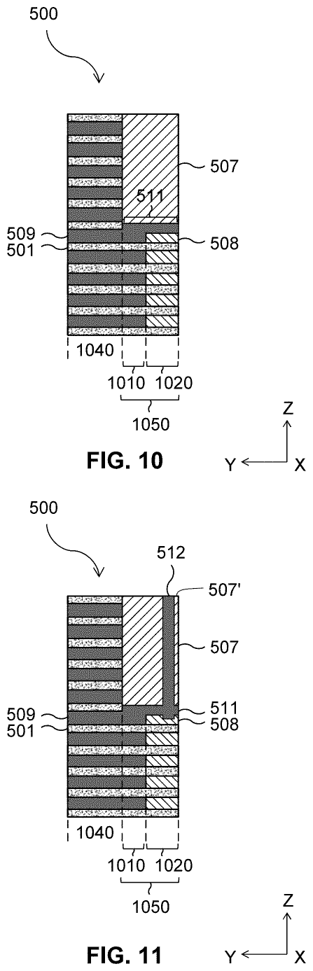

In FIG. 10, conductive layers 509 can be formed to fill the void of the now removed second insulating layers 502 and sacrificial layer 506 in FIG. 9. As a result, the wall region 1040 can be formed of a stack of alternating conductive layers 509 and first insulating layers 501. The first staircase region 1010 can also include a stack of alternating conductive layers 509 and first insulating layers 501. The second staircase region 1020 can include a stack of alternating second insulating layers 508 and first insulating layers 501 with a contact pad 511 formed on top of the stack. As shown, the conductive layer 509 can be zigzagged at each step S70 to include the contact pad 511 over the second insulating layer 508 in the second staircase region 1020.

The conductive layers 509 can be formed by atomic layer deposition, and can be made of a conductive material, such as tungsten. For example, an atomic layer can initially be formed on all surfaces of the void of the removed second insulating layers 502 and sacrificial layer 506 in FIG. 9, including the upper surface 501′, lower surface 501″, and side surface 501′ of the first insulating layers 501, the lower surface 507″ and side surface 507′″ of the third insulating layer 507, the upper surface 508′ and the side surface 508′ of the second insulating layer 508. Then, a successive atomic layer can be formed on top of the preceding atomic layer, which is repeated until the entire void is filled with the conductive material.

In FIG. 11, a contact structure 512 can be formed in the second staircase region 1020. The contact structure 512 can be made of the same conductive material as and integrally formed with the contact pad 511, making the contact structure 512 electrically coupled with a respective conductive layer 509. Further, the contact structure 512 can be electrically coupled with a respective word line in an array region. Additionally, while the contact structure 512 is shown as extending from an upper surface 507′ of the third insulating layer 507, through the contact pad 511, and into the second insulating layer 508, it should be understood that the contact structure 406 can also extend to the contact pad 511 without extending into the underlying stack or extend through the contact pad 511 and further into the underlying stack.

Still in FIG. 11, the first staircase region 1010 corresponds to the conductive staircase region 210 in FIGS. 2 and 410 in FIG. 4B. The second staircase region 1020 corresponds to the insulated staircase region 220 in FIGS. 2 and 420 in FIG. 4C. The wall region 1040 corresponds to the wall region 240 in FIGS. 2 and 440 in FIG. 4A.

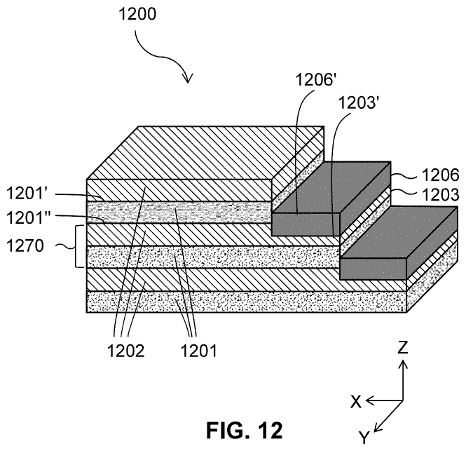

FIG. 12 is a cross-sectional view taken along the line EE′ in FIG. 7. The semiconductor structure 1200 can have a plurality of steps 1270, with each step including a second insulating layer 1202 over a first insulating layer 1201 that are made of different insulating materials. For each step 1270, the second insulating layer 1202 can include a recess 1203, with an upper surface 1203′ below a lower surface 1201″ of the first insulating layer 1201 of an adjacent step located immediately above the respective second insulating layer 1202. The step 1270 can further include a contact pad 1206 in the recess 1203 that has an upper surface 1206′ between an upper surface 1201′ and a lower surface 1201″ of the first insulating layer 1201 of an adjacent step located immediately above the respective recess 1203. In some embodiments, a third insulating layer can be formed over the contact pads 1206 of the second insulating layers 1202. While only two steps are shown, it should be understood that various numbers of layers and steps can be used to meet specific design requirements.

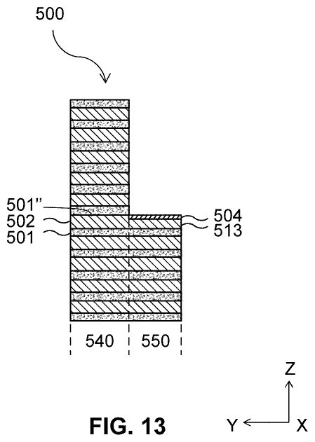

FIG. 13 shows an alternative embodiment to the manufacturing step shown in FIG. 6. Instead of forming a recess 503 as shown in FIG. 6, in this embodiment, a top portion 504 of the second insulating layer 502 of each step S70 can be chemically treated to form a new layer 504, while the layer 513 immediately below the new layer 504 can remain part of the second insulating layer 502. Specifically, the new layer 504 can be treated so that the chemical bonds can be broken and dangling bonds can be exposed. Accordingly, a subsequent deposition process can have more nucleation sites, leading to smoother films and eliminating void formation. The chemical treatment of the top portion 504 of the second insulating layer 502 of each step S70 can include plasma treatment, wet etch, dry etch, chemical vapor deposition, and the like. For example, helium plasma can be used to bombard silicon nitride surface to break Si-N bonds and form Si dangling bonds.

Subsequently, the rest manufacturing process can then proceed as described above, beginning in FIG. 7 with a sacrificial layer 506 being formed within and over the chemically modified layer 504 in FIG. 13. During this process, the chemically modified layer 504 can be converted to be part of the sacrificial layer 506.

Note that in an alternative embodiment, the manufacturing step shown in FIG. 6 can be skipped. Instead of forming a recess 503 as shown in FIG. 6, in this embodiment, the second insulating layer 502 is kept intact as shown in FIG. 5. Subsequently, the rest of the manufacturing process can then proceed as described above, beginning with a sacrificial layer being formed over the intact second insulating layer 502 in a similar way to what is demonstrated in FIG. 7 (not shown).

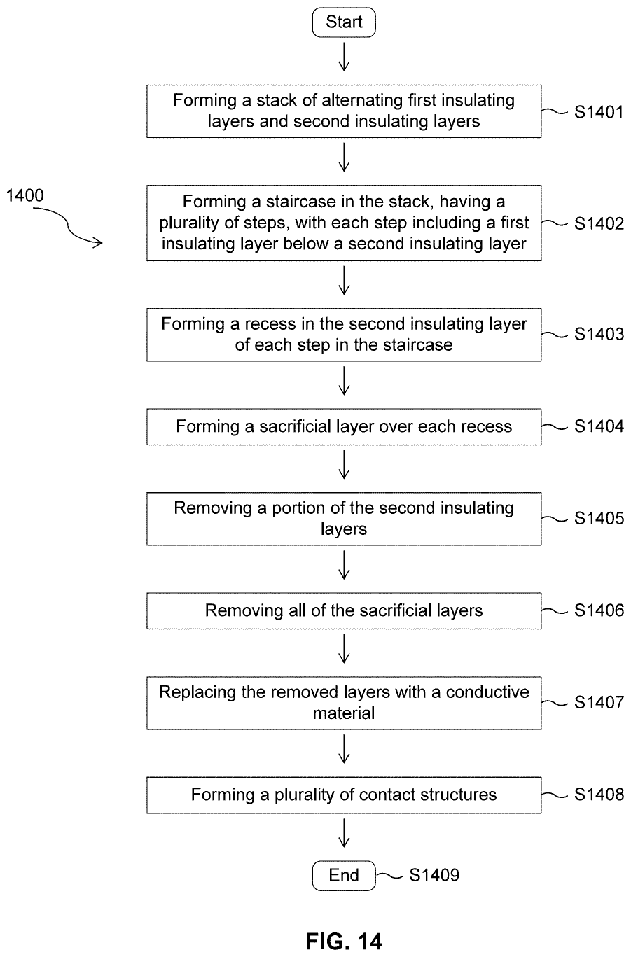

FIG. 14 is a flowchart of an exemplary process 1400 for manufacturing an exemplary semiconductor device, in accordance with embodiments of the disclosure. The process 1400 begins with step S1401 where a stack of alternating first insulating layers and second insulating layers can be formed. The first insulating layers and second insulating layers can be made of different materials.

The process 1400 then proceeds to step S1402 where a staircase having a plurality of steps can be formed in the stack, with each step including a second insulating layer over a first insulating layer. The stack can also have a wall region adjacent to the staircase. In some embodiments, the wall region can be flat as illustrated in FIG. 3A or stepped as in FIG. 3B. The semiconductor structure can also include an array region, some slit structures, and a third insulating layer over the entire stack.

The process 1400 then proceeds to step S1403 where a recess can be formed on the second insulating layer of each step in the staircase. An etching process, e.g., plasma treatment, can be performed here to selectively etch the second insulating layers.

At step S1404 of the process 1400, a sacrificial layer can be formed over each recess of the second insulating layers. A selective deposition process can be performed to deposit a sacrificial material over the recess. The upper surface of the sacrificial layer can be between the upper surface and the lower surface of the first insulating layer of an adjacent step above each respective recess.

The process 1400 then proceeds to step 1405, where a portion of the second insulating layers can be removed, dividing the staircase into a first staircase region without second insulating layers and a second staircase region with second insulating layers. The second insulating layers in a wall region and an array region of the semiconductor device can also be removed. The removal process can be a first wet etching process.

The process 1400 then proceeds to step 1406, where all the sacrificial layers can be removed. The removal process can be a second wet etching process where an etchant reaches the sacrificial layers via the empty space of removed second insulating layers.

At step S1407, conductive layers can be formed in the space of removed second insulating layers and sacrificial layers. A deposition process, e.g., atomic layer deposition, can be performed to conformally and controllably fill the space without voids. The wall region can include a stack of alternating conductive layers and first insulating layers. The first staircase region can also include a stack of alternating conductive layers and first insulating layers. The second staircase region can include a conductive layer, i.e., a contact pad, over a stack of alternating second insulating layers and first insulating layers. In some embodiments, the removed second insulating layers in an array region can also be filled with the same conductive material to serve as word lines. The contact pad in the second staircase region can be electrically coupled with a word line via a respective conductive layer in the first staircase region and a respective conductive layer in the wall region.

The process 1400 then proceeds to step 1408, where a plurality of contact structures can be formed in the second staircase region. The contact structures can extend from the upper surface of a third insulating layer to the contact pads in the second staircase region. Hence, a contact structure can be electrically coupled with a respective word line via a respective contact pad. A contact structure can be made of the same material as and integrally formed with a respective contact pad.

It should be noted that additional steps can be provided before, during, and after the process 1400, and some of the steps described can be replaced, eliminated, or performed in a different order for additional embodiments of the process 1400. For example, a plurality of channel structures can be formed in an array region of the stack during the process 1400. The channel structures can extend from the substrate through the stack of alternating insulating layers and conductive layers.

The various embodiments described herein offer several advantages. For example, the formation of a contact structure can be a high-aspect-ratio etching process, which makes it difficult to precisely control the depth of a contact structure. A contact structure that punches through a respective word line in related examples can lead to short-circuiting two or more word lines. In the present disclosure, however, a contact structure can be electrically coupled with a respective word line via a contact pad over a stack of insulating layers. Hence, a contact structure can extend though the contact pad into the underlying stack, rendering the etching process easier.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method for fabricating a semiconductor device, comprising:
forming a stack of alternating first insulating layers and first sacrificial layers over a semiconductor substrate;
forming a staircase in the stack having a plurality of steps, with at least a step of the staircase including a first sacrificial layer of the first sacrificial layers over a first insulating layer of the first insulating layers;
forming a second sacrificial layer over the first sacrificial layer; and
replacing a portion of the first sacrificial layer and the second sacrificial layer with a conductive material that forms a contact pad.

2. The method of claim 1, further comprising forming a recess in the first sacrificial layer prior to forming a second sacrificial layer over the first sacrificial layer.

3. The method of claim 1, further comprising performing a chemical treatment on a top portion of the first sacrificial layer prior to forming a second sacrificial layer over the first sacrificial layer.

4. The method of claim 3, wherein the chemical treatment breaks chemical bonds and forms dangling bonds in the top portion of the first sacrificial layer so that the second sacrificial layer diffuses into and deposits over the chemically treated top portion of the first sacrificial layer.

5. The method of claim 1, wherein replacing the portion of the first sacrificial layer and the second sacrificial layer with the conductive material further comprises:
removing a portion of the first sacrificial layer that provides access to the second sacrificial layer;
removing the second sacrificial layer; and
depositing the conductive material into a space of the removed first and second sacrificial layers.

6. The method of claim 5, further comprising:
performing a first wet etching process that removes the portion of the first sacrificial layer; and
performing a second wet etching process that removes the second sacrificial layer.

7. The method of claim 5, wherein:
at least a remaining portion of the first sacrificial layer under the second sacrificial layer is kept from being removed, so that the conductive material fills the space of the removed second sacrificial layer to form a contact pad over the remaining portion of the first sacrificial layer.

8. The method of claim 7, wherein:
the conductive material fills the space of the removed first sacrificial layer to form a conductive layer, the conductive layer forming an integral layer with the contact pad; and
the contact pad is horizontally on the step, in contact with the remaining portion of the first sacrificial layer and a portion of the conductive layer.

9. The method of claim 5, further comprising forming a contact structure in conductive connection with the contact pad.

10. The method of claim 9, further comprising:
forming at least an array of channel structures in the stack, the contact structure being configured to provide a control signal to the array of channel structures via the contact pad.

11. The method of claim 1, wherein the staircase is on a boundary or in the middle of the stack.

12. The method of claim 1, wherein an upper surface of the second sacrificial layer is between an upper surface and a lower surface of the first insulating layer of an adjacent step above the corresponding step.

13. A semiconductor device, comprising:
a staircase that is formed over a substrate and has a plurality of steps, with at least a step of the steps including a first insulating layer and a second layer arranged over the first insulating layer, the second layer including an insulating portion and a conductive portion; and
a contact pad that is arranged over the insulating portion and conductive portion of the second layer.

14. The semiconductor device according to claim 13, wherein the contact pad can be made of a same material as and integrally formed with the conductive portion of the second layer.

15. The semiconductor device according to claim 13, further comprising:
two walls positioned on opposite sides of the staircase, the two walls being formed of alternating first insulating layers and conductive layers that are vertically stacked over the substrate, where the first insulating layers of the walls are an extension of a corresponding first insulating layer of the step in two opposite directions.

16. The semiconductor device according to claim 15, wherein:
the conductive portion of the second layer is an extension of a corresponding conductive layer of the wall; and
the insulating portion of the second layer is a second insulating layer made of a different material than the first insulating layers of the wall.

17. The semiconductor device according to claim 15, further comprising:
a third insulating layer that is formed over the contact pad and extends to an upper surface of the wall; and
a contact structure that extends through the third insulating layer to the upper surface of the contact pad.

18. The semiconductor device according to claim 15, further comprising an array of channel structures that are formed in the alternating first insulating layers and conductive layers that are stacked over the substrate.

19. The semiconductor device according to claim 15, further comprising two slit structures on the boundaries of the two walls so that the two walls and the staircase are sandwiched between the two slit structures and that the insulating portion of the second layer in a step is located between the two slit structures.

20. The semiconductor device according to claim 13, wherein:
the staircase is on a boundary or in the middle of the stack; and
an upper surface of the contact pad is between an upper surface and a lower surface of an insulating layer of an adjacent step above the corresponding step.
